(19) United States
(12) Patent Application Publication
(10) Pub. No.: US 2026/0303304 A1
(43) Pub. Date: Oct. 1, 2026

(54) TRANSMITTER AND RECEIVER FOR TRANSMITTING AND RECEIVING MULTI-LEVEL SIGNAL AND SYSTEM INCLUDING THE SAME

(71) Applicants: SK hynix Inc., Gyeonggi-do (KR); Seoul National University R&DB Foundation, Seoul (KR)

(72) Inventors: Jeongeun SONG, Gyeonggi-do (KR); Wooseok CHOI, Seoul (KR)

(21) Appl. No.: 19/369,325

(22) Filed: Oct. 27, 2025

(30) Foreign Application Priority Data
Mar. 26, 2025 (KR) 10-2025-0038452

(51) Int. Cl. H04L 5/00; H03K 7/02; H04L 25/49

(52) U.S. Cl. CPC H04L 5/0092; H03K 7/02; H04L 25/4919

(57) ABSTRACT

A system includes a plurality of channels; a transmitter configured to convert multi-bit data into a plurality of multi-level signals, and transmit the plurality of multi-level signals to the plurality of channels; and a receiver configured to receive the plurality of multi-level signals from the plurality of channels, and convert the plurality of multi-level signals into the multi-bit data, wherein the plurality of multi-level signals form a symbol corresponding to the multi-bit data.

### CROSS-REFERENCE TO RELATED APPLICATION

The present application claims priority to Korean Patent Application No. 10-2025-0038452, filed on Mar. 26, 2025, which is incorporated herein by reference in its entirety.

### BACKGROUND

### 1. Technical Field

Embodiments relate to a transmitter for transmitting a multi-level signal, a receiver for receiving the same, and a system including the same.

### 2. Related Art

Pulse Amplitude Modulation level-3 (PAM3) technology transmitting signals with one of three levels can be implemented with a unipolar transmission method using one channel and/or a differential transmission method using two channels.

FIG. 1 illustrates the unipolar transmission method.

In FIG. 1, the three levels are indicated as Level 0, Level 1, and Level 2, in order of increasing voltage. The reference voltage between Level 0 and Level 1 is indicated as a first reference voltage VRN, and the reference voltage between Level 1 and Level 2 is indicated as a second reference voltage VRP.

According to the unipolar transmission method, a transmitter generates a voltage corresponding to one of the three levels and transmits it through a channel. A receiver identifies the level by providing a received input voltage VIN through the channel to two samplers 11 and 12.

The first sampler 11 compares the input voltage VIN with the first reference voltage VRN to generate a first sample signal OUT1. The second sampler 12 compares the input voltage VIN with the second reference voltage VRP to generate a second sample signal OUT2.

The relationship between the level of the input voltage VIN and the sample signals OUT1 and OUT2 is shown in FIG. 1 (i.e., OUT1=f(VIN−VRN), OUT2=f(VIN−VRP)).

As illustrated in FIG. 1, in the unipolar transmission method, the samplers must identify a difference corresponding to half of the level interval, making it susceptible to noise.

Furthermore, in the unipolar transmission method, the transmitter transmits one symbol over one channel, and the receiver uses two samplers per channel, each using two reference voltages to identify the received signal.

FIG. 2 is a diagram illustrating a differential transmission method.

According to the differential transmission method, a transmitter generates differential voltages corresponding to one of three levels, including positive and negative voltages, and transmits the differential voltages through two channels. A receiver provides the positive input voltage VINP and the negative input voltage VINN received through the two channels to two differential samplers 21 and 22 to identify the levels.

The first differential sampler 21 generates a first sample signal OUT1 based on the result of subtracting the voltage obtained by subtracting the second reference voltage VRP from the first reference voltage VRN from the voltage obtained by subtracting the negative input voltage VINN from the positive input voltage VINP (i.e., OUT1=f((VINP−VINN)−(VRN−VRP))).

The second differential sampler 22 generates a second sample signal OUT2 based on the result of subtracting the voltage obtained by subtracting the first reference voltage VRN from the second reference voltage VRP from the voltage obtained by subtracting the negative input voltage VINN from the positive input voltage VINP (i.e., OUT2=f((VINP−VINN)−(VRP−VRN))).

The relationship between the level of the positive input voltage VINP and the sample signals OUT1 and OUT2 is shown in FIG. 2.

As shown in FIG. 2, according to differential transmission method, the differential sampler must identify a difference corresponding to one level interval, making it less sensitive to noise.

According to this differential transmission method, the transmitter transmits one symbol over two channels, and the receiver uses two samplers per channel, each using two reference voltages to identify the received signal.

The unipolar transmission method offers the advantages of higher pin and energy efficiency compared to the differential transmission method, and the differential transmission method is more resistant to noise such as crosstalk.

To achieve the same noise characteristics as the differential transmission method in the unipolar transmission, swing width of the channel signal must be doubled compared to differential transmission, resulting in increased power consumption.

Furthermore, PAM3 technology based on unipolar and differential transmission methods uses two reference voltages in the receiver, which further increases power consumption of the receiver.

Conventional PAM3 technology, based on unipolar and differential transmission methods, can only express three levels in a single transmission and reception cycle. Therefore, for communicating 3-bit data, the transmitter encodes and transmits 3-bit data twice, using eight different combinations and the receiver then determines the reception level twice and decodes it into 3-bit data.

Consequently, the transceiver requires memory for both transmissions and receptions, resulting in additional space and power consumption. Furthermore, if the receiver decodes the data during the two cycles, there's a risk of mixing data in neighboring cycles, leading to errors in decoding. Therefore, to prevent these timing errors, additional circuitry or error-correcting code transmission is required.

### SUMMARY

In accordance with an embodiment of the present disclosure, a system may include a plurality of channels, a transmitter configured to convert multi-bit data into a plurality of multi-level signals, and transmit the plurality of multi-level signals to the plurality of channels; and a receiver configured to receive the plurality of multi-level signals from the plurality of channels, and convert the plurality of multi-level signals into the multi-bit data, wherein the plurality of multi-level signals form a symbol corresponding to the multi-bit data.

In accordance with an embodiment of the present disclosure, a transmitter may include an encoder configured to convert multi-bit data into a plurality of control signals; and a transmitter circuit configured to generate a multi-level signal according to the plurality of control signals, and transmit the multi-level signal to a plurality of channels, wherein the plurality of multi-level signals form a symbol corresponding to the multi-bit data.

In accordance with an embodiment of the present disclosure, a receiver may include a receiver circuit configured to receive a plurality of multi-level signals from a plurality of channels, and generate a plurality of differential signal pairs based on the plurality of multi-level signals; a sampler array configured to generate a plurality of sample signals based on the plurality of differential signal pairs and a common voltage; and a decoder configured to output a multi-bit data based on the plurality of sample signals, wherein the plurality of multi-level signals form a symbol corresponding to multi-bit data.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates a unipolar transmission method.

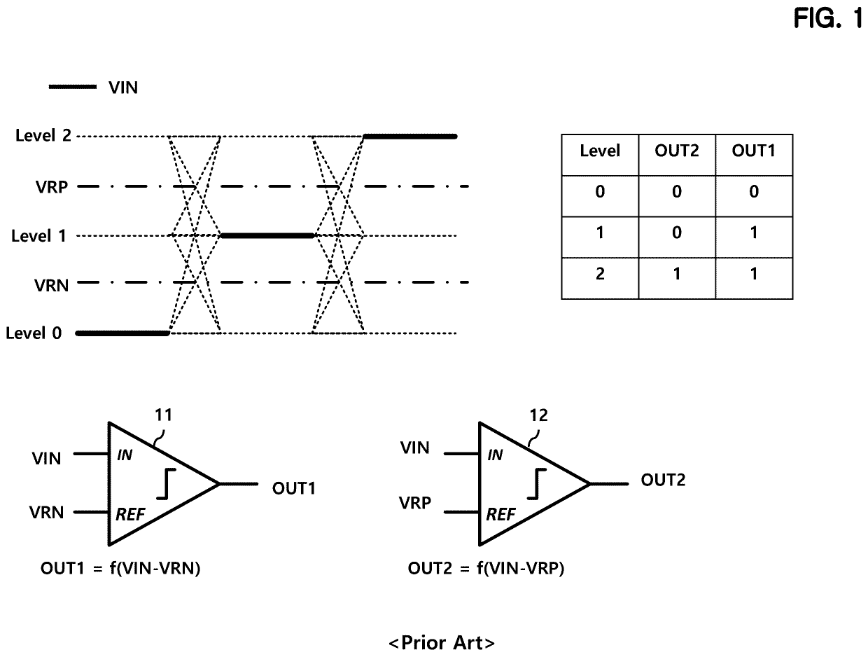

FIG. 2 illustrates a differential transmission method.

FIG. 3 illustrates a system according to an embodiment of the present disclosure.

FIG. 4 illustrates a transmitter circuit according to an embodiment of the present disclosure.

FIG. 5 illustrates an operation of a transmitter circuit according to an embodiment of the present disclosure.

FIG. 6 illustrates a receiver circuit according to an embodiment of the present disclosure.

FIG. 7 illustrates an operation of a receiver circuit according to an embodiment of the present disclosure.

FIG. 8 illustrates a sampler array according to an embodiment of the present disclosure.

FIG. 9 illustrates an operation of a sampler array according to an embodiment of the present disclosure.

FIG. 10 is a waveform diagram illustrating an operation of a sampler array according to an embodiment of the present disclosure.

FIG. 11 illustrates an operation of a decoder according to an embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

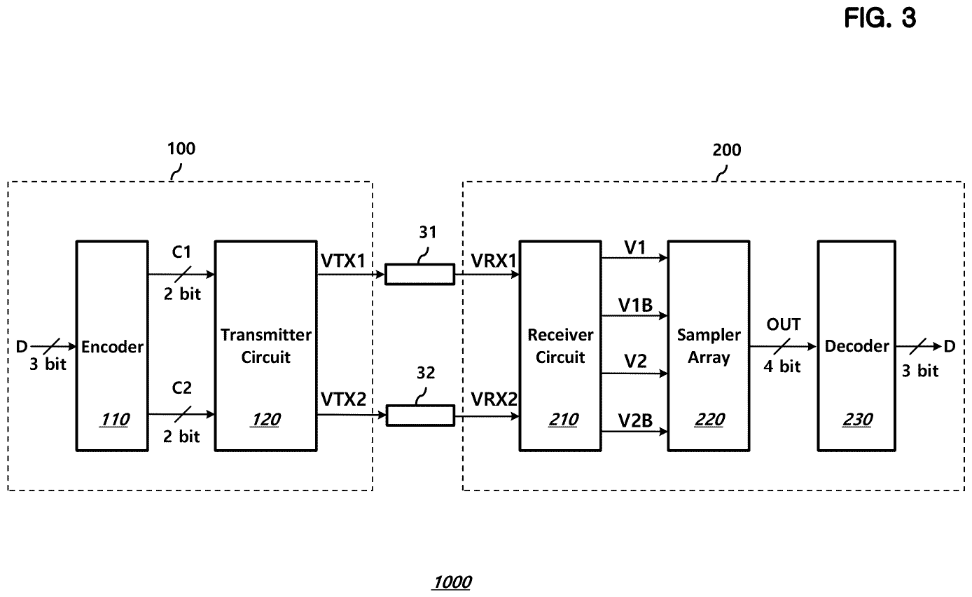

FIG. 3 is a block diagram illustrating a system 1000 according to an embodiment of the present disclosure.

Referring to FIG. 3, the system 1000 includes a transmitter 100, a receiver 200, and a plurality of channels 31 and 32.

The number of channels may vary depending on the embodiment, but only two channels are illustrated in this embodiment.

In this embodiment, the transmitter 100 encodes 3-bit data D and transmits the data in a PAM3 manner via two channels 31 and 32.

The transmitter 100 includes an encoder 110 and a transmitter circuit 120.

In this embodiment, the encoder 110 converts the 3-bit data into a 2-bit first control signal C1 and a 2-bit second control signal C2.

The first control signal C1 is used to generate a corresponding PAM3 signal and drive the first channel 31. The second control signal C2 is used to generate a corresponding PAM3 signal and drive the second channel 32.

The operation of the encoder 110 is described in detail below.

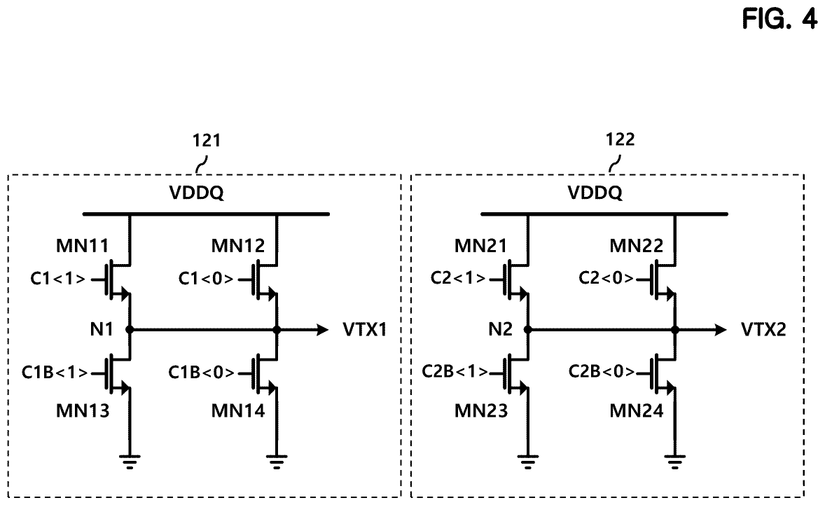

FIG. 4 is a circuit diagram illustrating a transmitter circuit according to an embodiment of the present disclosure, e.g., a transmitter circuit 120 of FIG. 3.

Referring to FIG. 4, the transmitter circuit 120 includes a first transmitter circuit 121 that drives the first channel 31 according to the first control signal C1 and a second transmitter circuit 122 that drives the second channel 32 according to the second control signal C2.

The first transmitter circuit 121 includes NMOS transistors MN11 and MN12 whose sources and drains are connected between a power supply node VDDQ and a first node N1, and NMOS transistors MN13 and MN14 whose sources and drains are connected between the first node N1 and a ground node.

In some embodiments, the first control signal C1 may include an upper bit C1<1>, a lower bit C1<0>, an inverted upper bit C1B<1>, and an inverted lower bit C1B<0>. The upper bit C1<1> of the first control signal C1 is applied to the gate of the NMOS transistor MN11. The lower bit C1<0> of the first control signal C1 is applied to the gate of the NMOS transistor MN12.

The inverted upper bit C1B<1>, which is an inversion of the upper bit C1<1> of the first control signal C1, is applied to the gate of the NMOS transistor MN13. The inverted lower bit C1B<0>, which is an inversion of the lower bit C1<0> of the first control signal C1, is applied to the gate of the NMOS transistor MN14.

The first node N1 is connected to the first channel 31 of FIG. 3 and has a first transmission voltage VTX1 during a transmission operation.

The second transmission circuit 121 includes NMOS transistors MN21 and MN22 whose sources and drains are connected between a power supply node and a second node N2, and NMOS transistors MN23 and MN24 whose sources and drains are connected between the second node N2 and a ground node.

In some embodiments, the second control signal C2 may include an upper bit C2<1>, a lower bit C2<0>, an inverted upper bit C2B<1>, and an inverted lower bit C2B<0>. The upper bit C2<1> of the second control signal C2 is applied to the gate of the NMOS transistor MN21. The lower bit C2<0> of the second control signal C2 is applied to the gate of the NMOS transistor MN22.

An inverted upper bit C2B<1>, which is an inversion of the upper bit C2<1> of the second control signal C2, is applied to the gate of the NMOS transistor MN23. An inverted lower bit C2B<0>, which is an inversion of the lower bit C2<0> of the second control signal C2, is applied to the gate of the NMOS transistor MN24.

The second node N2 is connected to the second channel 32 of FIG. 3 and has a second transmission voltage VTX2 during transmission operation.

While the present embodiment uses an N-over-N structured transmitter circuit using NMOS transistors, the type of transistor may vary depending on the embodiment.

If the type of transistor varies, each bit of the control signal may also vary, and thus the output signal of the encoder 110 may also vary.

Since this can be easily known from the present disclosure by those skilled in the art, a repetitive description will be omitted.

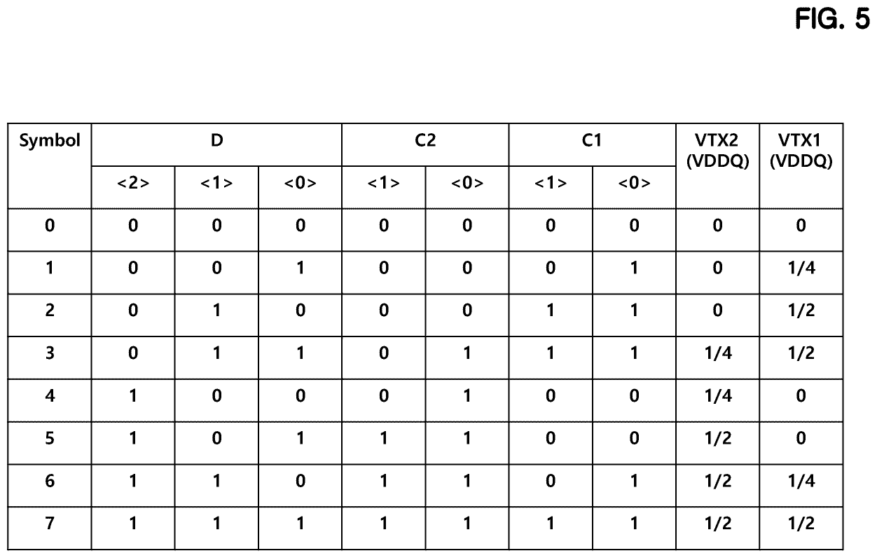

FIG. 5 is a table illustrating an operation of the transmitter 100 according to one embodiment of the present disclosure.

In the illustrated example of FIG. 5, the data D input to the encoder 110 is a 3-bit data, each corresponding to one of eight symbols.

The first control signal C1 and the second control signal C2 corresponding to the eight symbols are as illustrated in FIG. 5.

Hereinafter, it is assumed that the turn-on impedance of the NMOS transistors MN11, MN12, MN13, and MN14 is 100 ohms and the pull-down termination resistor connected to the first channel 31 on the receiver 200 is 50 ohms.

It is also assumed that the turn-on impedance of the NMOS transistors MN21, MN22, MN23, and MN24 is 100 ohms and the pull-down termination resistor connected to the second channel 32 on the receiver 200 is 50 ohms.

For example, data D “000” corresponds to symbol 0, and the corresponding first control signal C1 and second control signal C2 are “00” and “00,” respectively.

When the first control signal C1 is “00,” the NMOS transistors MN11 and MN12 are turned off and the NMOS transistors MN13 and MN14 are turned on in FIG. 4.

When the second control signal C2 is “00,” the NMOS transistors MN21 and MN22 are turned off and the NMOS transistors MN23 and MN24 are turned on, in FIG. 4.

Accordingly, the second transmission voltage VTX2 becomes 0 V.

For example, data D “011” corresponds to symbol 3, and the corresponding first control signal C1 and second control signal C2 are “11” and “01,” respectively.

When the first control signal C1 is “11,” the NMOS transistors MN13 and MN14 are turned off and the NMOS transistors MN11 and MN12 are turned on, in FIG. 4.

Therefore, the first transmission voltage VTX1 becomes VDDQ/2V.

When the second control signal C2 is “01,” the NMOS transistors MN21 and MN24 in FIG. 4 are turned off and the NMOS transistors MN22 and MN23 are turned on.

Therefore, the second transmission voltage VTX2 becomes VDDQ/4V.

FIG. 5 illustrates a first control signal C1, a second control signal C2 encoded by the encoder 110 in response to 3-bit data D, and a first transmission voltage VTX1 and a second transmission voltage VTX2 corresponding thereto.

In FIG. 5, OV corresponds to Level 0 of the PAM3 signal, VDDQ/4 V corresponds to Level 1 of the PAM3 signal, and VDDQ/2 V corresponds to Level 2 of the PAM3 signal.

As shown in FIG. 5, in the present embodiment, there is no case where both the first transmission voltage VTX1 and the second transmission voltage VTX2 are VDDQ/4.

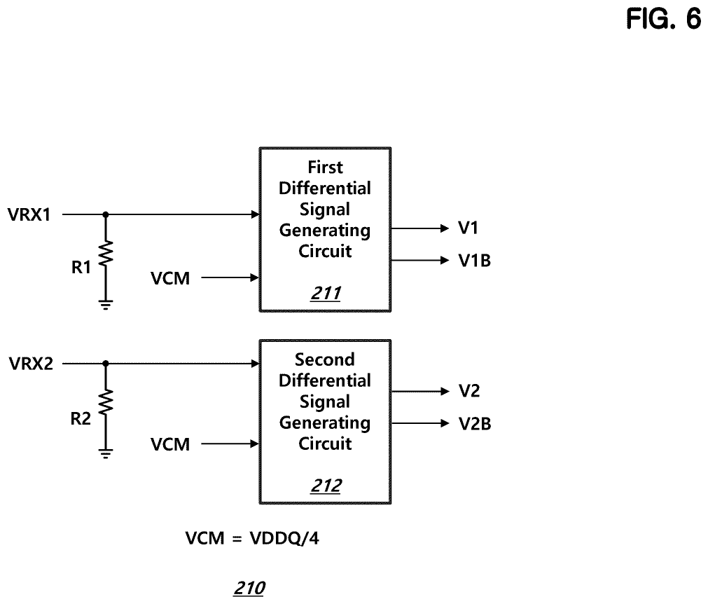

FIG. 6 is a block diagram illustrating the receiver circuit 210 according to an embodiment of the present disclosure.

Referring to FIG. 6, the receiver circuit 210 includes a first differential signal generating circuit 211 that generates a pair of first differential voltages V1 and V1B using a pull-down termination resistor R1 connected to a first channel 31, a first reception voltage VRX1, and a common voltage VCM. Hereinafter, V1 is referred to as a positive first differential voltage, and V1B is referred to as a negative first differential voltage.

Furthermore, the receiver circuit 210 includes a second differential signal generating circuit 212 that generates a pair of second differential voltages V2 and V2B using a pull-down termination resistor R2 connected to a second channel 32, a second reception voltage VRX2, and the common voltage VCM. Hereinafter, V2 is referred to as the positive second differential voltage, and V2B is referred to as the negative second differential voltage.

In this embodiment, the common voltage VCM corresponds to VDDQ/4V.

In other embodiments, the termination resistor may be included in a pull-up configuration, and in still other embodiments, the termination resistor may be omitted. Since the method of connecting the termination resistor can be designed in various ways by those skilled in the art, a detailed description thereof will be omitted.

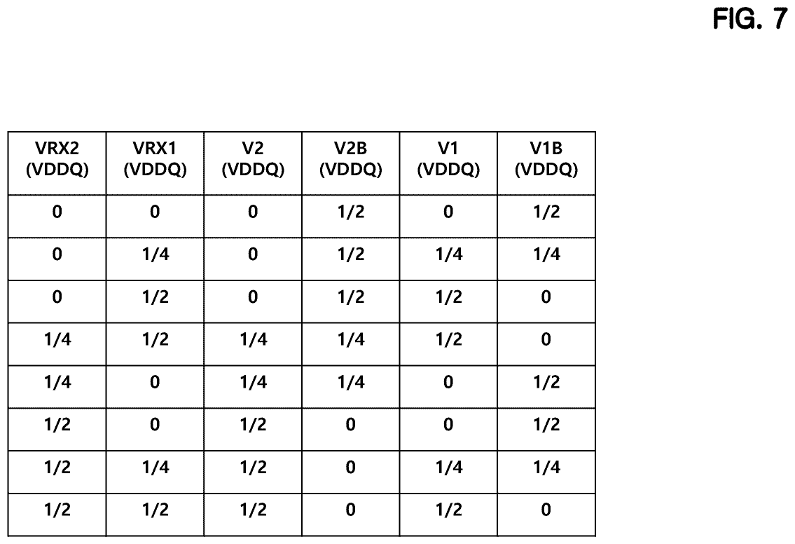

FIG. 7 illustrates an operation of a receiver circuit 210 according to an embodiment of the present disclosure.

The relationship between a pair of first differential voltages V1 and V1B and a first reception voltage VRX1 is as shown in Equation 1. Equation 1 assumes that the voltage gain of the first differential signal generating circuit 211 is 1.

$$V 1 = VRX 1 \qquad [ Equation 1 ]$$

$$V 1 B = 2 \times VCM - V 1$$

The relationship between a pair of second differential voltages V2 and V2B and the second reception voltage VRX2 is as shown in Equation 2. Equation 2 assumes that the voltage gain of the second differential signal generating circuit 212 is 1.

$$V 2 = VRX 2 \qquad [ Equation 2 ]$$

$$V 2 B = 2 \times VCM - V 2$$

FIG. 7 illustrates a first reception voltage VRX1 and a corresponding pair of first differential voltages V1 and V1B, and a second reception voltage VRX2 and a corresponding pair of second differential voltages V2 and V2B, according to the relationships in Equations 1 and 2.

For example, when the first reception voltage VRX1 is 0, the first differential voltages V1 and V1B are 0 and VDDQ/2, respectively.

For example, when the first reception voltage VRX1 is VDDQ/4, the first differential voltages V1 and V1B are VDDQ/4, respectively.

For example, when the first reception voltage VRX1 is VDDQ/2, the first differential voltages V1 and V1B are VDDQ/2 and 0, respectively.

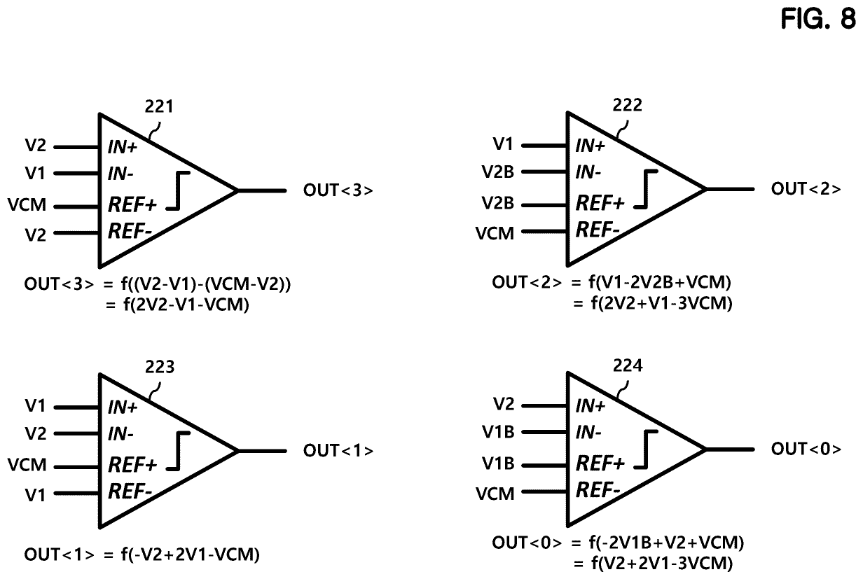

FIG. 8 is a circuit diagram illustrating the sampler array 220 according to an embodiment of the present disclosure.

In this embodiment, the sampler array 220 generates a 4-bit sample signal OUT using a pair of first differential voltages V1 and V1B, a pair of second differential voltages V2 and V2B, and the common voltage VCM. The sample signal OUT may include a zeroth bit OUT<0>, a first bit OUT<1>, a second bit OUT<2> and a third bit OUT<3>.

Hereinafter, the third bit OUT<3> of the sample signal OUT may be referred to as the first sample signal, the second bit OUT<2> of the sample signal OUT may be referred to as the second sample signal, the first bit OUT<1> of the sample signal OUT may be referred to as the third sample signal, and the zeroth bit OUT<0> of the sample signal OUT may be referred to as the fourth sample signal.

The sampler array 220 includes a first sampler 221 that generates a first sample signal OUT<3>, a second sampler 222 that generates a second sample signal OUT<2>, a third sampler 223 that generates a third sample signal OUT<1>, and a fourth sampler 224 that generates a fourth sample signal OUT<0>.

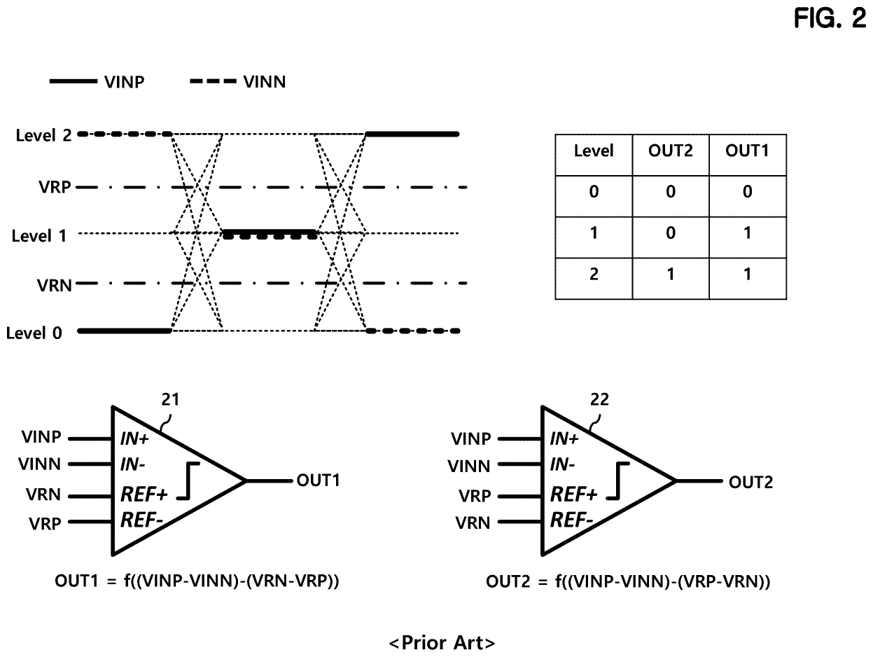

Each of the first sampler 221, the second sampler 222, the third sampler 223, and the fourth sampler 224 is identical to the differential sampler 21, 22 of FIG. 2.

Each of the first to fourth samplers 221, 222, 223, and 224 uses two signals selected from among four signals of two differential voltage pairs transmitted from two channels as positive and negative input voltages (i.e., IN+, IN−), uses one of the two selected signals as one of two reference voltages (i.e., REF+ or REF−), and use the common voltage VCM as the other of two reference voltages (i.e., REF− or REF+).

Specifically, the following is provided:

In the first sampler 221, a positive second voltage V2 is input as a positive input voltage IN+, a positive first voltage V1 is input as a negative input voltage IN−, the common voltage VCM is input as a positive reference voltage REF+, and a positive second voltage V2 is input as a negative reference voltage REF−.

Accordingly, the first sample signal OUT<3> has a value of “1” when a sign of the first comparison voltage 2V2−V1−VCM is positive, and a value of “0” when the sign of the first comparison voltage is negative.

In the second sampler 222, a positive first voltage V1 is input as a positive input voltage IN+, a negative second voltage V2B is input as a negative input voltage IN−, a negative second voltage V2B is input as a positive reference voltage REF+, and the common voltage VCM is input as a negative reference voltage REF−.

Accordingly, the second sample signal OUT<2> has a value of “1” when the sign of the second comparison voltage 2V2+V1−3VCM is positive, and a value of “0” when the sign of the second comparison voltage is negative.

In the third sampler 223, a positive first voltage V1 is input as a positive input voltage IN+, a positive second voltage V2 is input as a negative input voltage IN−, the common voltage VCM is input as a positive reference voltage REF+, and a positive first voltage V1 is input as a negative reference voltage REF−.

Accordingly, the third sample signal OUT<1> has a value of “1” when the sign of the third comparison voltage −V2+2V1−VCM is positive, and a value of “0” when the sign of the third comparison voltage is negative.

In the fourth sampler 224, a positive second voltage V2 is input as the positive input voltage IN+, a negative first voltage V1B is input as the negative input voltage IN−, a negative first voltage V1B is input as the positive reference voltage REF+, and a common voltage VCM is input as the negative reference voltage REF−.

Accordingly, the fourth sample signal OUT<0> has a value of “1” when the sign of the fourth comparison voltage V2+2V1−3VCM is positive, and a value of “0” when the sign of the fourth comparison voltage is negative.

In this way, unlike conventional differential transmission methods, the first to fourth samplers 221, 222, 223, and 224 perform sampling operations using a single reference voltage, thereby reducing power consumption in the circuit that generates the reference voltage.

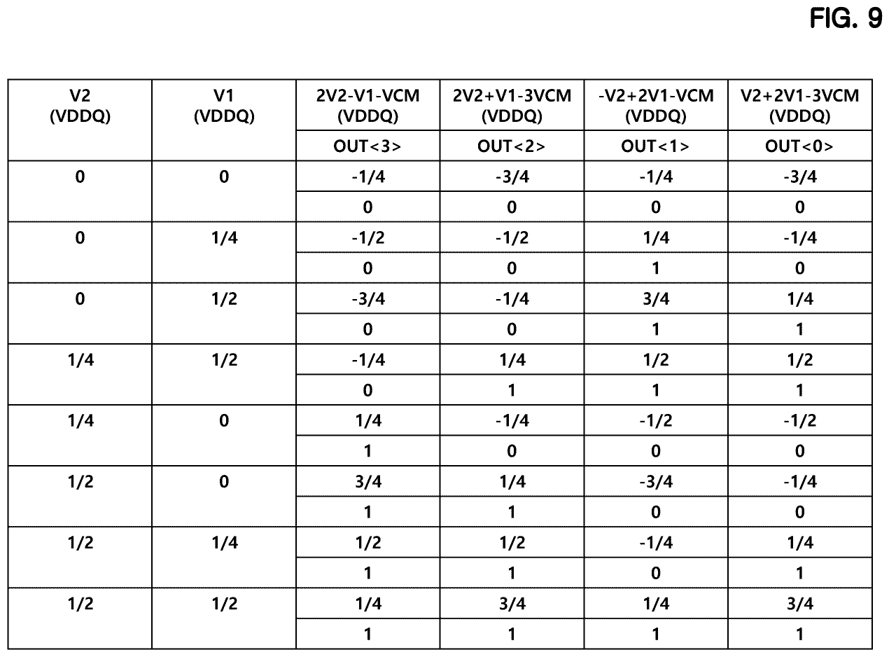

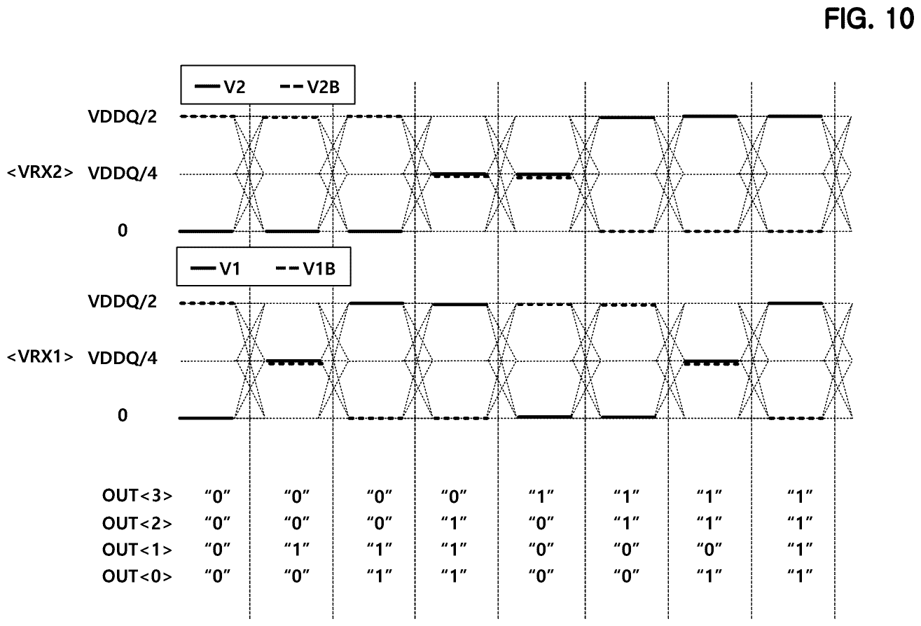

FIG. 9 illustrates an operation of the sampler array 220 according to an embodiment of the present disclosure, and FIG. 10 is a waveform diagram illustrating an operation of the sampler array 220 according to an embodiment of the present disclosure.

As illustrated in FIG. 10, the first reception voltage VRX1 and the second reception voltage VRX2 are PAM3 signals received through the first channel 31 and the second channel 32 of FIG. 3.

An example will be described where the positive second voltage V2 is VDDQ/4 and the positive first voltage V1 is VDDQ/2.

As illustrated in FIGS. 8 and 10, the first comparison voltage 2V2−V1−VCM is −VDDQ/4, therefore the first sample signal OUT<3> is “0”, the second comparison voltage 2V2+V1−3VCM is VDDQ/4, therefore the second sample signal OUT<2> is “1”, the third comparison voltage −V2+2V1−VCM is VDDQ/2, therefore the third sample signal OUT<1> is “1”, and the fourth comparison voltage V2+2V1−3VCM is VDDQ/2, therefore the fourth sample signal OUT<0> is “1”.

Accordingly, when the second voltage V2 is VDDQ/4 and the positive first voltage V1 is VDDQ/2, that is, when the second reception voltage VRX2 is VDDQ/4 and the first reception voltage VRX1 is VDDQ/2, the sample signal OUT “0111” is generated.

In other cases, the 4-bit sample signal OUT received corresponding to the first channel 31 and the second channel 32 can be determined in a similar manner.

Furthermore, as shown in FIG. 9, the minimum magnitude of the first to fourth comparison voltages is VDDQ/4, which is the same as the interval between the two levels of the PAM3 signal. Accordingly, the first to fourth samplers have good noise resistance, as in the differential transmission method.

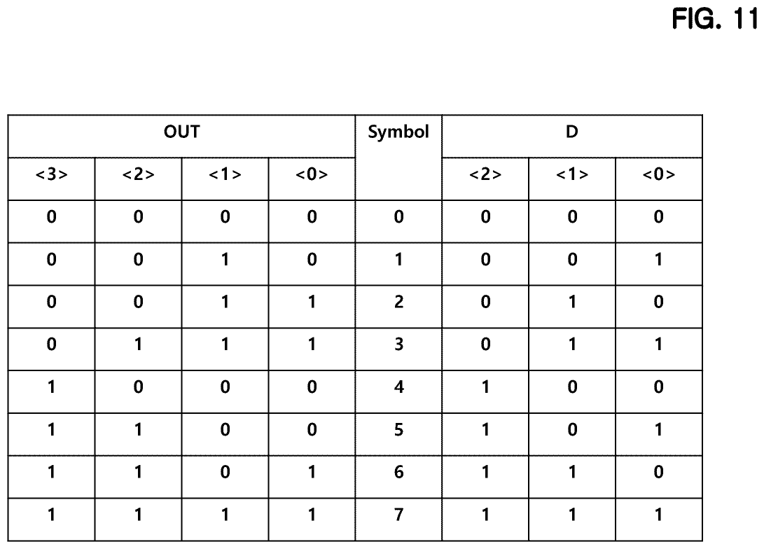

FIG. 11 illustrates an operation of the decoder 230 according to an embodiment of the present disclosure.

The decoder 230 operates in the reverse way of the encoder 110 and outputs 3-bit data D corresponding to the 4-bit sample signal OUT.

For example, the decoder 230 outputs data D “011” corresponding to symbol 3 for the sample signal OUT “0111”, and data D “100” corresponding to symbol 4 for the sample signal OUT “1000.”

The data D corresponding to other sample signals OUT is self-evident from the operation of the encoder 110, so a repetitive description will be omitted.

The above describes an embodiment of converting 3-bit data into a PAM3 format signal and transmitting the PAM3 format signal over two channels.

Those skilled in the art will readily be able to derive techniques for converting data containing a larger number of bits into a multi-level signal in PAM3 or another format and transmitting it over two or more channels, based on the present disclosure.

Although some embodiments have been described above for illustrative purposes, various changes and modifications may be made to the above-described embodiments.

What is claimed is:

1. A system comprising:
a plurality of channels;
a transmitter configured to convert multi-bit data into a plurality of multi-level signals, and transmit the plurality of multi-level signals to the plurality of channels; and
a receiver configured to receive the plurality of multi-level signals from the plurality of channels, and convert the plurality of multi-level signals into the multi-bit data,
wherein the plurality of multi-level signals form a symbol corresponding to the multi-bit data.

2. The system of claim 1, wherein the transmitter comprises:
an encoder configured to convert the multi-bit data into a plurality of control signals; and
a transmitter circuit configured to generate the multi-level signal according to the plurality of control signals, and transmit the multi-level signal to the plurality of channels.

3. The system of claim 2, wherein the transmitter circuit includes a first transmitter circuit and a second transmitter circuit,
wherein the plurality of channels includes a first channel and a second channel,
wherein the first transmitter circuit provides, to the first channel, a first multi-level signal among the plurality of multi-level signals, and
wherein the second transmitter circuit provides, to the second channel, a second multi-level signal among the plurality of multi-level signals.

4. The system of claim 1, wherein the receiver comprises:
a receiver circuit configured to receive the plurality of multi-level signals from the plurality of channels, and generate a plurality of differential signal pairs based on the plurality of multi-level signals;
a sampler array configured to generate a plurality of sample signals based on the plurality of differential signal pairs and a common voltage; and
a decoder configured to output a multi-bit data based on the plurality of sample signals.

5. The system of claim 4, wherein the receiver circuit includes a first receiver circuit and a second receiver circuit,
wherein the first receiver circuit generates a first differential signal pair according to the common voltage and a first multi-level signal among the plurality of multi-level signals, and
wherein the second receiver circuit generates a second differential signal pair according to the common voltage and a second multi-level signal among the plurality of multi-level signals.

6. The system of claim 5, wherein the sampler array includes a plurality of samplers generating the plurality of sample signals,
wherein each of the plurality of samplers includes a differential sampler including a positive input voltage terminal, a negative input voltage terminal, a positive reference voltage terminal, and a negative reference voltage terminal, and
wherein each of the plurality of samplers generates a comparison signal by providing two signals selected from the first differential signal pair and the second differential signal pair to the positive input voltage terminal and the negative input voltage terminal, by providing the common voltage to one of the positive reference voltage terminal and the negative reference voltage terminal, and by providing a signal selected from the first differential signal pair and the second differential signal pair to the other of the positive input voltage terminal and the negative input voltage terminal, and generates a sample signal according to a sign of the comparison signal.

7. The system of claim 6, wherein the signal provided to the other of the positive reference voltage and the negative reference voltage includes one of two signals selected from the first differential signal pair and the second differential pair.

8. The system of claim 1, wherein the multi-bit data includes 3-bit data, the multi-level signal includes a Pulse Amplitude Modulation level-3 (PAM3) signal, and a number of the plurality of channels is 2.

9. A transmitter comprising:
an encoder configured to convert multi-bit data into a plurality of control signals; and
a transmitter circuit configured to generate a multi-level signal according to the plurality of control signals, and transmit the multi-level signal to a plurality of channels,
wherein the plurality of multi-level signals form a symbol corresponding to the multi-bit data.

10. The transmitter of claim 9, wherein the transmitter circuit includes a first transmitter circuit and a second transmitter circuit,
wherein the plurality of channels includes a first channel and a second channel,
wherein the first transmitter circuit provides, to the first channel, a first multi-level signal among the plurality of multi-level signals, and
wherein the second transmitter circuit provides, to the second channel, a second multi-level signal among the plurality of multi-level signals.

11. The transmitter of claim 10, wherein the first transmitter circuit includes:
a plurality of first transistors, each having a source and a drain connected between a power supply node and a first node; and
a plurality of second transistors, each having a source and a drain connected between the first node and a ground node,
wherein gates of the plurality of first transistors receives a first control signal among the plurality of control signals, gates of the plurality of second transistors receives an inversion of the first control signal, and the first node is connected to the first channel.

12. A receiver comprising:
a receiver circuit configured to receive a plurality of multi-level signals from a plurality of channels, and generate a plurality of differential signal pairs based on the plurality of multi-level signals;
a sampler array configured to generate a plurality of sample signals based on the plurality of differential signal pairs and a common voltage; and
a decoder configured to output a multi-bit data based on the plurality of sample signals,
wherein the plurality of multi-level signals form a symbol corresponding to multi-bit data.

13. The receiver of claim 12, wherein the receiver circuit includes a first receiver circuit and a second receiver circuit,
wherein the first receiver circuit generates a first differential signal pair according to the common voltage and a first multi-level signal among the plurality of multi-level signals, and
wherein the second receiver circuit generates a second differential signal pair according to the common voltage and a second multi-level signal among the plurality of multi-level signals.

14. The receiver of claim 13, wherein the sampler array includes a plurality of samplers generating the plurality of sample signals,
wherein each of the plurality of samplers includes a differential sampler including a positive input voltage terminal, a negative input voltage terminal, a positive reference voltage terminal, and a negative reference voltage terminal, and
wherein each of the plurality of samplers generates a comparison signal by providing two signals selected from the first differential signal pair and the second differential signal pair to the positive input voltage terminal and the negative input voltage terminal, by providing the common voltage to one of the positive reference voltage terminal and the negative reference voltage terminal, and by providing a signal selected from the first differential signal pair and the second differential signal pair to the other of the positive input voltage terminal and the negative input voltage terminal, and generates a sample signal according to a sign of the comparison signal.

15. The receiver of claim 14, wherein the signal provided to the other of the positive reference voltage and the negative reference voltage includes one of two signals selected from the first differential signal pair and the second differential pair.

16. The receiver of claim 12, wherein the multi-bit data includes 3-bit data, the multi-level signal includes a Pulse Amplitude Modulation level-3 (PAM3) signal, and a number of the plurality of channels is 2.
